(19) United States
(12) Patent Application Publication
(10) Pub. No.: US 2026/0159377 A1
(43) Pub. Date: Jun. 11, 2026

(54) MEMS CONTACT SWITCH

(71) Applicant: Robert Bosch GmbH, Stuttgart (DE)

(72) Inventor: Christoph Schelling, Stuttgart (DE)

(21) Appl. No.: 19/402,204

(22) Filed: Nov. 26, 2025

(30) Foreign Application Priority Data
Dec. 10, 2024 (DE) 10 2024 136 829.2

(51) Int. Cl. B81B 7/00; H01H 1/00

(52) U.S. Cl. CPC B81B 7/0016; H01H 1/0036; B81B 2201/018; B81B 2203/0109; B81B 2203/0127; B81B 2203/0163; B81B 2203/04; H01H 2001/0084

(57) ABSTRACT

A MEMS contact switch. The MEMS contact switch includes a substrate, and a micromechanical switching element, which is movably suspended above the substrate. The micromechanical switching element includes a first subelement and a second subelement. The first subelement is suspended using a first suspension spring, and the second subelement is suspended on the first subelement using a second suspension spring. A first electrically conductive contact surface is disposed on the second subelement and a second electrically conductive contact surface is disposed on an opposite surface above the substrate with a gap-like spacing. A first capacitive control electrode is disposed on the surface above the substrate. A second capacitive control electrode is disposed on the surface above the substrate.

### CROSS REFERENCE

The present application claims the benefit under 35 U.S.C. § 119 of Germany Patent Application No. DE 10 2024 136 829.2 filed on Dec. 10, 2024, which is expressly incorporated herein by reference in its entirety.

### FIELD

Micromechanical (MEMS) contact switches are a compact and comparatively long-lasting alternative to conventional relays. However, the reliability of MEMS contact switches still falls short of the service life requirements of many applications. Ideally, they should achieve service lives of approximately 10 billion switching cycles with the highest possible switching capacities and at temperatures up to 125° C. This would open up entirely new fields of application for MEMS contact switches.

It is therefore important to understand the failure pattern and the underlying triggering aging mechanisms. The sticking of the contacts has proven to be a service life-limiting failure pattern. This causes the switch to remain closed even after the control voltage is removed. This is primarily due to an adhesive force that increases with the number of switching cycles.

MEMS switches with only one separately controllable control electrode or control potential, which have resilient stops that provide a higher restoring force for separating the contacts from one another are described in U.S. Pat. No. 8,704,116 B2 and Germany Patent Application No. DE 10 2021 204 951 A1. However, the stops are made of the same materials.

### SUMMARY

An object of the present invention is to provide a micromechanical switch with an extended service life, in particular with a higher number of switching cycles.

The present invention relates to a MEMS contact switch. According to an example embodiment of the present invention, the MEMS contact switch comprises a substrate, and a micromechanical switching element, which is movably suspended above the substrate, wherein the micromechanical switching element comprises a first subelement and a second subelement, wherein the first subelement is suspended above the substrate by means of at least one first suspension spring, wherein the second subelement is suspended on the first subelement by means of at least one second suspension spring, wherein at least one first electrically conductive contact surface is disposed on the second subelement and at least one second electrically conductive contact surface is disposed on an opposite surface above the substrate with a gap-like spacing. The switch comprises a first capacitive control electrode, which is disposed on the surface above the substrate and is configured to deflect the first subelement of the movable element in a first direction perpendicular to the main extension plane of the substrate by a first travel distance. The switch also comprises a second capacitive control electrode, which is disposed on the surface above the substrate and is configured to deflect the second subelement of the movable element in the first direction perpendicular to the main extension plane of the substrate by a second travel distance, so that the first contact surface and at least the second contact surface create an electrically conductive contact.

The MEMS switch according to the present invention enables a better-defined switching behavior and thus a longer service life measured in switching cycles than conventional components.

According to an example embodiment of the present invention, stops, in particular resilient stops, are advantageously provided on the first subelement or on the second subelement to limit the first or second travel distance. The resilient first or second stop surfaces can preferably be made of different materials than the electrical contact surfaces. Non-ductile hard materials such as dielectrics or hard metals are advantageously used. The subelements of the movable element can be configured as bending beams or membranes. An advantageous embodiment of the present invention provides that there is a third contact surface in addition to a second contact surface and the first contact surface functions only as a contact bridge. There is therefore no current flow across most of the micromechanical switching element, but only from the second contact surface via the first contact surface to the third contact surface. The second, third and possibly further contact surfaces can likewise be disposed on a movable element. Like the first control electrode, the second control electrode can be configured such that the second subelement of the movable element can be brought to a resilient second mechanical stop. The first and second control electrodes can be separately controllable. The first and second control electrodes can be electrically connected to one another and have different gap widths to the movable element. The spring constants of the suspension of the first and the second subelement can have different strengths. The second control electrode can be connected to the first control electrode via an electrical damping element or delay element. A plurality of second subelements can be resiliently connected to an in particular frame-like first subelement and controlled by a common second control electrode.

Further advantageous embodiments of the present invention can be found in the disclosure herein.

The present invention also relates to a suitable control method for a MEMS contact switch.

The present invention advantageously enables a softer landing of the micromechanical switching part during the switching-on process. A reduced collision impulse of the meeting contact surfaces ensures less material fatigue in the region of the electrical contact and consequently increased service life, as long as electrical aging effects do not prevail. This is achieved by two control potentials that can be switched at different times and resilient stop surfaces made of different material combinations than the material of the electrical contact surfaces. Resilient stops elastically store collision energy when the contact closes and can make it available again when the contact opens. A further advantage arises from the fact that the restoring force of the two suspension springs is available to overcome the adhesive forces and accelerate the contacts apart to open the switch. This also leads to an increase in the service life of the switch, because local spot welds up to a larger cross-sectional area can still be separated and the contact surfaces spend less time in the critical near field responsible for degradation when opening.

### BRIEF DESCRIPTION OF THE DRAWINGS

FIGS. 1A and 1B show a MEMS contact switch according to the present invention in a first embodiment example in a cross-section AA′ and in a plan view.

FIGS. 2A to 2C show the MEMS contact switch according to the present invention in the first embodiment example in a cross-section BB′ in three operating states.

FIG. 3 shows a MEMS contact switch according to the present invention in a second embodiment example with a membrane-like second subelement in a cross-section.

FIG. 4 shows a MEMS contact switch according to the present invention in a third embodiment example with a plurality of second subelements in plan view.

FIG. 5 schematically shows a method for actuating a MEMS contact switch according to the present invention.

### DETAILED DESCRIPTION OF EXAMPLE EMBODIMENTS

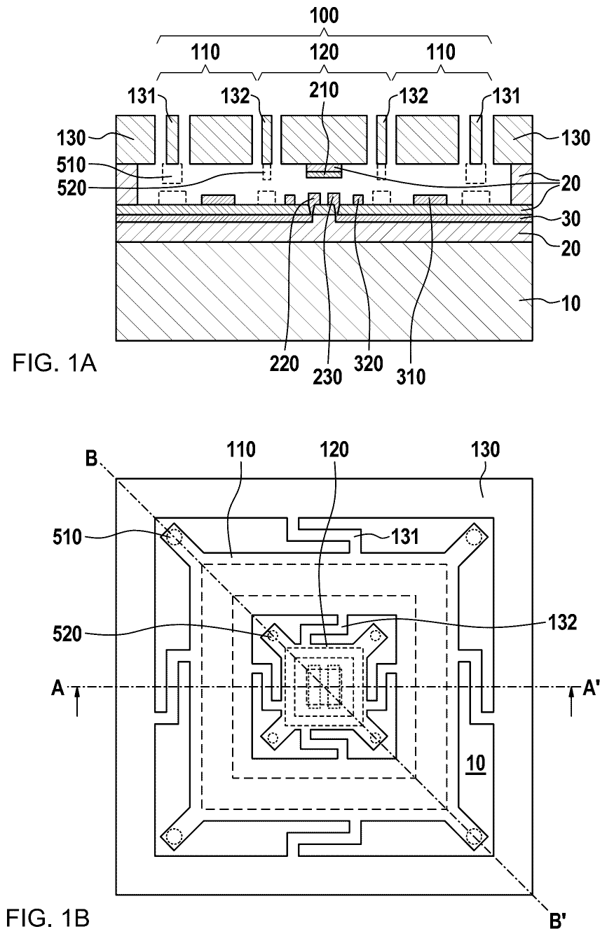

FIGS. 1A and 1B show a MEMS contact switch according to the present invention in a first embodiment example in a cross-section AA′ and in a plan view.

In section AA′, FIG. 1A shows a micromechanical device comprising a substrate 10 and a movable micromechanical switching part 100 disposed above the substrate parallel to a main extension plane of the substrate. A first electrically conductive contact surface 210 is disposed on an underside of the switching part facing the substrate. A second electrical contact surface 220 and a third electrical contact surface 230 are disposed opposite on an opposite surface above the substrate. These are connected to a structured conductive layer 30. The device also comprises a plurality of insulation layers 20 which are disposed above the substrate, below and above the conductive layer 30 and below the contact surfaces 210, 220, 230. The movable micromechanical switching part 100 comprises a first subelement 110, which is movably suspended above the substrate by means of first suspension springs 131 on an armature 130. A second subelement 120 is in turn movably suspended on the first subelement by means of second suspension springs 132. The first electrically conductive contact surface 210 is disposed on the underside of the second subelement, electrically separated by an insulation layer 20. A first control electrode 310 is disposed on the surface above the substrate 10 below the first subelement 110 and is configured to pull the first subelement a first travel distance in the direction of the substrate 10. A second control electrode 320 is disposed on the surface above the substrate 10 below the second subelement 120 and is configured to additionally pull the second subelement by a second travel distance in the direction of the substrate 10, so that the first contact surface 210 establishes an electrically conductive connection between the second contact surface 220 and the third contact surface 230 as a contact bridge.

FIG. 1B shows the micromechanical functional elements in a plan view from above. The armature 130 surrounds the movable micromechanical switching part 100 like a frame. The first subelement 110 surrounds the second subelement 120 like a frame. Resilient first stops 510 limit a deflection of the first subelement in the direction of the substrate 10 to the first travel distance. Resilient second stops 520 limit a deflection of the second subelement in the direction of the substrate 10 to the sum of the first travel distance and the second travel distance.

Alternatively, other shapes of the armature or a suspension of the first subelement on a plurality of armatures are possible.

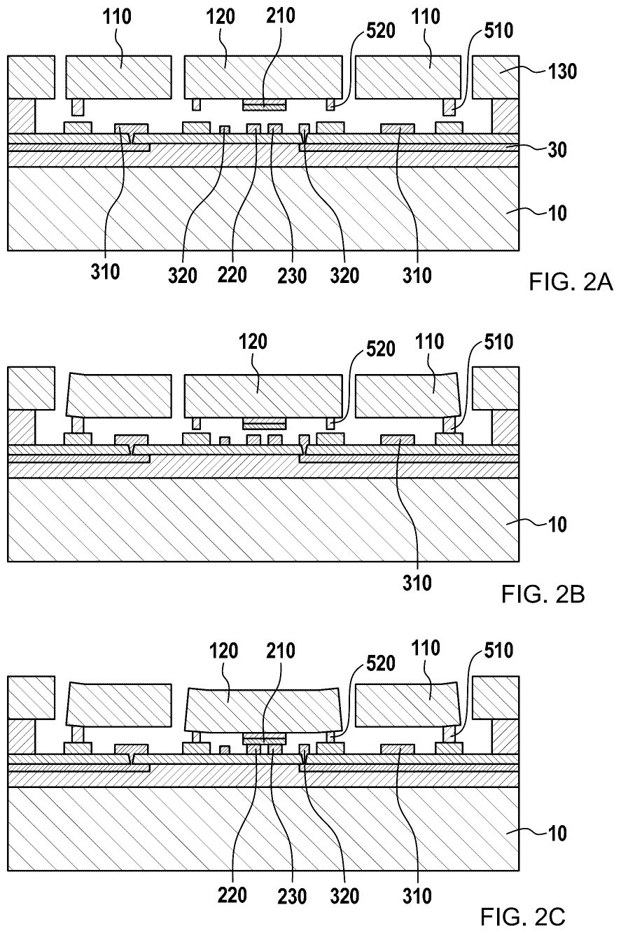

FIGS. 2A to 2C show the MEMS contact switch according to the present invention in the first embodiment example in a cross-section BB′ in three operating states.

FIG. 2A shows the MEMS contact switch according to the present invention of FIG. 1B in cross-section BB′, a section through the first and second stops 510, 520 in an unswitched initial state. No control voltage is being applied between the first and second control electrodes 310 and 320 and the movable micromechanical switching element 100 with the first subelement 110 and the second subelement 120. The first contact surface 210 on the one hand and the second and third contact surfaces 320 and 330 on the other hand are separated by a gap. The electrical contact is therefore open.

FIG. 2B shows the MEMS contact switch according to the present invention in a first switching stage. A first control voltage is applied between the first control electrode 310 and the first subelement 110 and the second subelement 120. This pulls the movable micromechanical switching element 100 a first travel distance in the direction of the substrate until the first stops 510 rest against it. The second subelement 120 is moved along with it and the gap between the first contact surface 210 on the one hand and the second and third contact surface 320 and 330 on the other hand is reduced accordingly. The electrical contact is still open, however.

FIG. 2C shows the MEMS contact switch according to the present invention in a second switching stage.

A first control voltage continues to be applied between the first control electrode 310 and the first subelement 110. A second control voltage is applied between the second control electrode 320 and the second subelement 120. This pulls the second subelement 120 a second travel distance in the direction of the substrate 10 until the second stops 520 rest against it. The first contact surface 210 rests against the second and the third contact surface 220 and 230 so that the electrical contact is closed.

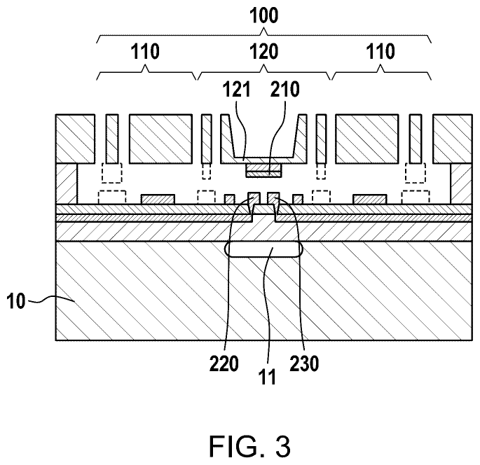

FIG. 3 shows a MEMS contact switch according to the present invention in a second embodiment example with a membrane-like second subelement in a cross-section. The second subelement 120 is configured as a thin membrane 121 in a frame. The first contact surface 210 is disposed on the underside of the membrane, and is therefore resilient. The second contact surface 220 and the third contact surface 230 are likewise disposed on a membrane; in this case above a cavity 11. The cavity is disposed in or above the substrate 10.

The first contact surface or the second and third contact surface 220, 230 can alternatively be disposed on a bending beam (not depicted).

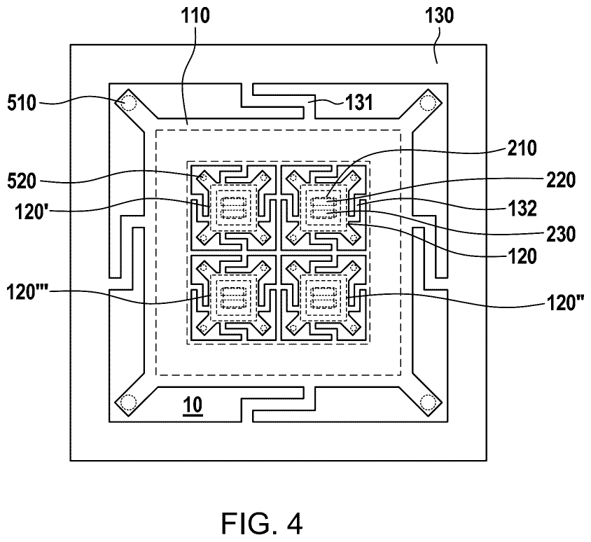

FIG. 4 shows a MEMS contact switch according to the present invention in a third embodiment example with a plurality of second subelements in plan view.

The first subelement 110 surrounds a plurality of second subelements 120, 120′, 120″, 120″′ like a frame. Each second subelement 120 comprises a first contact surface 210 on its underside. Second and third contact surfaces 220 and 230 are disposed respectively opposite on the substrate 10.

Each individual second subelement can also have a separately controllable control electrode 320, so that up to four contacts can be established.

The MEMS contact switch according to the present invention comprises at least one movable element resiliently suspended on a substrate. In a preferred embodiment of the present invention, the element itself consists of a frame subelement and at least one contact subelement which is again resiliently connected to it. A first electrically conductive contact surface is disposed on the contact subelement. Spaced apart from the first contact surface by a gap are at least a second contact surface, preferably also a third electrical contact surface such that when the travel distance is reduced, an electrical contact between first, second and third contact surfaces is closed. To reduce the gap, a control electrode is provided, which is configured to bring the first frame subelement of the movable element to a resilient first mechanical stop. A second control electrode is configured to pull the second subelement of the movable element into full contact only when the frame subelement rests against the first stop. It is not sufficient to apply electrical voltage to only one of the control electrodes. If both control electrodes are activated, however, a useful signal can propagate from the second contact surface via the first contact surface to the third contact surface. The first and the second control electrode extend in non-overlapping regions of the first or second subelement, so that the subelements can be controlled separately for deflection. This two-stage design makes it possible to achieve a softer landing of the electrical contact surface. A softer landing reduces the collision impulse and ensures less material fatigue in the region of the electrical contact. The mechanical service life of the contact increases as long as electrical aging effects do not prevail. Another positive effect is that the resilient stops can elastically store collision energy when the contact closes and can make it available again when the contact opens. This increases the electrical robustness of the switch. To open the switch, the restoring force of the two suspension springs is available to overcome the adhesive forces and accelerate the contacts apart. This also leads to an increase in the service life of the switch, because local spot welds up to a larger cross-sectional area can still be separated and the contact surfaces spend less time in the critical near field responsible for degradation when opening.

The resilient first stop surfaces or the resilient second stop surfaces can preferably be made of different materials than the electrical contact surfaces. In particular non-ductile hard materials such as dielectrics (SiO₂, Si₃N₄, etc.) or hard metals (Pt, Ir, . . . ) are used. The resilient stops do not have to perform a current-conducting function and can therefore advantageously be made of mechanically more robust, more long-term stable hard materials without having to consider their electrical resistance.

The subelements of the movable element can be configured as bending beams or membranes. These two embodiments advantageously enable flexibility in the configuration of the mechanical contact, because the surfaces can fit together more snugly.

The second, third and further contact surfaces can likewise be disposed on a movable element; for example on a membrane or a bending beam. This embodiment advantageously enables flexibility in the configuration of the mechanical contact, because the surfaces can fit together more snugly.

Like the first control electrode, the second control electrode can be configured such that the second subelement of the movable element can be brought to a resilient second mechanical stop. As in the case of the first resilient stops, this too enables a reduction of the collision impulse and an increase in the restoring forces.

The first and second control electrodes can be separately controllable. This allows a large amount of flexibility in the timing of the control of the switch and enables a longer service life. A first control voltage can therefore be used to cause the first frame element to hit the first stops without the second contact element automatically closing the contact. Only the additional separate second control voltage then leads to the contact being closed.

The first and second control electrodes can be electrically connected to one another and have different gap widths to the movable element or different electrode surfaces or different spring constants. A first control voltage can therefore be used to cause the first frame-like subelement to hit the first stop and then automatically cause the second subelement to hit and establish electrical contact. The control electrodes are configured such that, in the initial state, only the stop condition for the first subelement is met, but when the first stop occurs, the stop condition for the second subelement is met as well and electrical contact between the first, second and, if applicable, third contact surfaces is established.

The second control electrode can be connected to the first control electrode via an electrical damping element or a delay element. This is an alternative way to manage with only one control voltage. The delay element is preferably set such that it is tuned to the natural frequency of the second subelement. Ideally, the control signal arrives after half a period when the second subelement is at the lower reversal point of its movement.

A plurality of second subelements can be resiliently connected to an in particular frame-like first subelement and controlled by a common control electrode. This makes it possible to distribute the current densities and heat densities of the MEMS contact switch over multiple contacts, which increases the robustness. Alternatively, however, the plurality of second subelements can also be controlled by separate control electrodes.

### Operating Method for the MEMS Contact Switch

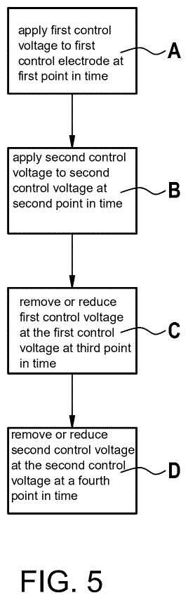

FIG. 5 schematically shows a method for actuating a MEMS contact switch according to the present invention.

The method comprises the following steps for closing the MEMS contact switch:
Step (A): applying a first control voltage to the first control electrode at a first point in time to deflect the first subelement in the first direction.
Step (B): applying a second control voltage to the second control electrode at a second point in time to deflect the second subelement in the first direction, so that the first contact surface and at least the second contact surface create an electrically conductive contact.

The time difference between the first point in time and the subsequent second point in time can advantageously be greater than half a period of a first natural vibration mode of the movable element.

The method also comprises the following steps for closing the MEMS contact switch:
Step (C): removing or reducing the first control voltage at the first control electrode at a third point in time,
Step (D): removing or reducing the second control voltage at the second control electrode at a fourth point in time, so that the first contact surface and at least the second contact surface interrupt an electrically conductive contact.

The third point in time and the fourth point in time are not to be understood as a mandatory temporal sequence. The fourth point in time can therefore occur before the third point in time or coincide with it.

### List of Reference Signs

10 Substrate
11 Cavity
20 Insulation layer
30 Conductive layer
100 Movable micromechanical switching element
110 First subelement
120 Second subelement
121 Membrane
130 Armature
131 First suspension spring
132 Second suspension spring
210 First electrically conductive contact surface
220 Second electrically conductive contact surface
230 Third electrically conductive contact surface
310 First control electrode
320 Second control electrode
510 First stop
520 Second stop

What is claimed is:

1. A MEMS contact switch, comprising:
a substrate with a main extension plane;
a micromechanical switching element which is movably suspended above the substrate, wherein the micromechanical switching element includes a first subelement and a second subelement, wherein the first subelement is suspended using at least one first suspension spring, wherein the second subelement is suspended on the first subelement using at least one second suspension spring, wherein at least one first electrically conductive contact surface is disposed on the second subelement and at least one second electrically conductive contact surface is disposed on an opposite surface above the substrate with a gap-like spacing;
a first capacitive control electrode, which is disposed on the opposite surface above the substrate and is configured to deflect the first subelement of the movable element in a first direction perpendicular to the main extension plane of the substrate by a first travel distance; and
a second capacitive control electrode, which is disposed on the opposite surface above the substrate and is configured to deflect the second subelement of the movable element in the first direction by a second travel distance, so that the first contact surface and the second contact surface create an electrically conductive contact.

2. The MEMS contact switch according to claim 1, wherein a first electrically conductive contact surface is disposed on the second subelement and a second electrically conductive contact surface and a third electrically conductive contact surface are disposed opposite on the substrate with a gap-like spacing, wherein the first electrically conductive contact surface is configured as a contact bridge for establishing an electrically conductive connection between the second electrically conductive contact surface and the third electrically conductive contact surface.

3. The MEMS contact switch according to claim 1, wherein the first subelement is suspended above the substrate using the least one first suspension spring which is on at least one armature.

4. The MEMS contact switch according to claim 3, wherein the armature surrounds the micromechanical switching element like a frame.

5. The MEMS contact switch according to claim 1, wherein the first subelement surrounds the second subelement like a frame.

6. The MEMS contact switch according to claim 5, wherein the first subelement a plurality of second subelements like a frame.

7. The MEMS contact switch according to claim 6, wherein the second control electrode is configured to deflect a plurality of second subelements of the movable element in the first direction.

8. The MEMS contact switch according to claim 1, wherein the first subelement includes a resiliently configured first stop to limit the deflection of the first subelement in the first direction.

9. The MEMS contact switch according to claim 8, wherein the second subelement includes a resiliently configured second stop to limit the deflection of the second subelement in the first direction.

10. The MEMS contact switch according to claim 7, wherein the first stop and/or the second stop include a material that is different from a material of the first contact surface and/or the second contact surface and/or the third contact surface.

11. The MEMS contact switch according to claim 1, wherein the first subelement and/or the second subelement is configured as a bending beam or a membrane.

12. The MEMS contact switch according to claim 1, wherein the at least one first suspension spring has a first spring constant and the at least one second suspension spring has a second spring constant, wherein the first spring constant is not equal to the second spring constant.

13. The MEMS contact switch according to claim 1, wherein the first control electrode and the second control electrode can be controlled separately from one another.

14. The MEMS contact switch according to claim 1, wherein the first control electrode and the second control electrode are electrically connected to one another and have different spacings to the movable micromechanical switching element.

15. The MEMS contact switch according to claim 13, wherein the first control electrode and the second control electrode are connected to one another via an electrical damping element and/or delay element.

16. A method for actuating a MEMS contact switch, the MEMS contact switch including:
a substrate with a main extension plane,
a micromechanical switching element which is movably suspended above the substrate, wherein the micromechanical switching element includes a first subelement and a second subelement, wherein the first subelement is suspended using at least one first suspension spring, wherein the second subelement is suspended on the first subelement using at least one second suspension spring, wherein at least one first electrically conductive contact surface is disposed on the second subelement and at least one second electrically conductive contact surface is disposed on an opposite surface above the substrate with a gap-like spacing,
a first capacitive control electrode, which is disposed on the opposite surface above the substrate and is configured to deflect the first subelement of the movable element in a first direction perpendicular to the main extension plane of the substrate by a first travel distance, and
a second capacitive control electrode, which is disposed on the opposite surface above the substrate and is configured to deflect the second subelement of the movable element in the first direction by a second travel distance, so that the first contact surface and the second contact surface create an electrically conductive contact
the method comprising the following steps:
(A) applying a first control voltage to the first control electrode at a first point in time to deflect the first subelement in the first direction; and
(B) applying a second control voltage to the second control electrode at a second point in time to deflect the second subelement in the first direction, so that the first contact surface and at least the second contact surface create an electrically conductive contact.

17. The method for actuating a MEMS contact switch according to claim 16, further comprising the following steps:
(C) removing or reducing the first control voltage at the first control electrode at a third point in time; and
(D) removing or reducing the second control voltage at the second control electrode at a fourth point in time, so that the first contact surface and at least the second contact surface interrupt an electrically conductive contact.
